(19) United States
(12) Patent Application Publication
(10) Pub. No.: US 2011/0192443 A1
(43) Pub. Date: Aug. 11, 2011

(54) Electrical Connection and Support Assembly for a Photovoltaic Cell Having Rear Contacts, A Photovoltaic Module Including Such an Assembly, and a method of Fabricating Such a Module

(75) Inventors: Bernard CHEVIET, GRANDFONTAINE (FR); Gerard PERROD, BESANCON (FR); Klaus Werner BAMBERG, ST CHRISTOPHE ET LE LARIS (FR); Etienne SAINT-SERNIN, LYON (FR)

(73) Assignees: INTERPLEX SOPREC, SAINT-VIT (FR); APOLLON SOLAR, LYON (FR)

(21) Appl. No.: 13/022,056

(22) Filed: Feb. 7, 2011

(30) Foreign Application Priority Data
Feb. 11, 2010 (FR) 10 50985

(51) Int. Cl. H01L 31/05; H01L 31/0224; H01L 31/0232

(52) U.S. Cl. 136/244; 136/256; 438/65; 257/E31.129

(57) ABSTRACT

This electrical connection assembly is used for a photovoltaic cell (4) having rear electrical contacts. The assembly comprises at least one spacer-plate (10) of electrically insulating material suitable for having the rear face of the cell bearing against a first side (116) thereof in a position in which the connection terminals (46, 48) of the cell (4) are in register with through orifices (120, 122) in the spacer-plate (10). The assembly also includes at least two ribbons (20) of electrically conductive material arranged on a second side of the spacer-plate (10), opposite from the first side (116), and provided with contact elements (210, 212) suitable for making electrical contact with the connection terminals (46, 48) of the cell (4) through the orifices (120, 122) in the spacer-plate. Electrical contact between the contact elements (210, 212) and the connection terminals (46, 48) is established without soldering, under the effect of a resilient force.

The invention relates to an electrical connection assembly for a photovoltaic cell having rear contacts, i.e. having electrical connection terminals that are placed on its rear face that is opposite from its front face for exposure to light. The invention also relates to a photovoltaic module including, amongst other things, such an electrical connection and support assembly. Finally, the invention relates to a method of fabricating such a module.

In the field of capturing solar energy by means of photovoltaic cells, it is known to make photovoltaic modules by associating a plurality of photovoltaic cells between a support plate and a translucent plate that covers the photosensitive components of the various cells. Within such a module, the cells are generally electrically connected to one another by means of copper conductor strips that extend over the front face of the cell and then under the rear face of an adjacent cell so as to collect electricity produced by the various cells which are thus connected in series. Those conductor strips mask the front faces of the cells to some extent, thereby correspondingly reducing the yield of a module incorporating such conductor strips.

To mitigate that problem, it is known to make photovoltaic cells having a rear face, opposite from the face carrying the photovoltaic components, that is fitted with electrical connection terminals of both positive and negative types. With such cells, there is no longer any need to have an electrical conductor strip located over the front faces of the cells, thereby improving the energy yield of a module incorporating such cells. Devices that are presently available for connecting together such cells comprise printed circuits that are soldered or fitted to the rear faces of the cells, which operation is both complex and onerous to implement. One difficulty arises from the fact that the rear contact terminals of such a cell present two opposite polarities. It is necessary to connect the positive terminals to one another while isolating them from the negative terminals, and vice versa.

The invention seeks more particularly to remedy those drawbacks by proposing a novel electrical connection assembly for a photovoltaic cell, which assembly is particularly simple to implement and is also inexpensive.

To this end, the invention provides an assembly for electrically connecting a photovoltaic cell having a front face for exposing to sun light, and a rear face fitted with positive electrical connection terminals and with negative electrical connection terminals. The assembly comprises:
at least one spacer-plate of electrically insulating material suitable for having the rear face of the cell bear against a first side thereof in a position such that the connection terminals of the cell are in register with orifices passing through the spacer-plate; and
at least two ribbons of electrically conductive material arranged on a second side of the spacer-plate, opposite from the first side, each ribbon being provided with contact elements suitable for establishing electrical contact with the connection terminals of the cell bearing against the first side of the spacer-plate, through the orifices in the spacer-plate, electrical contact between the contact elements and the connection terminals being established without soldering, under the effect of a resilient force.

By means of the invention, the spacer-plate enables a photovoltaic cell to be pre-positioned bearing against a first side thereof while guaranteeing electrical insulation and selective contact between the electrical contact terminals provided on the rear face of said cell and the electrical interconnection ribbons. The spacer-plate also serves to maintain spacing between a support plate and a front plate of a module fitted with such an assembly. The free electrical contact, established without permanent fastener means between the contact elements and the terminals, is particularly easy to implement.

In aspects of the invention that are advantageous but not essential, such a connection and support assembly may incorporate one or more of the following technical characteristics taken in any technically feasible combination:
The spacer-plate is provided with at least one rib for pre-positioning the cell in two directions that are parallel to a face of the cell.
The spacer-plate is provided with a plurality of ribs that are compatible with mounting a photovoltaic cell with clearance.
Each ribbon comprises a plurality of electricity-collector strips, each fitted with a plurality of contact elements, and an electricity distributor strip connecting together the collector strips. Under such circumstances, provision may be made for the collector strips of the ribbon extend on either side of the distributor strip and to be perpendicular thereto, and for the collector strips situated on one side of the distributor strip to be offset along a longitudinal axis of the distributor strip relative to the collector strips situated on the other side of the distributor strip.
The spacer-plate is provided with at least a first row of orifices for placing in resister with negative terminals of a photovoltaic cell pressing against said spacer-plate, and a second row of orifices for placing in register with positive terminals of the same cell bearing against said spacer-plate.
The contact elements of the ribbons are elastically deformable tongues.
The tongues are obtained by cutting out and/or folding the ribbons.
The contact elements are formed integrally with the ribbons.

The invention also relates to a photovoltaic module comprising at least one photovoltaic cell having rear contact terminals, a translucent plate covering the front face of the cell, and a support plate towards which the rear face of the cell faces. This module comprises at least one support and connection assembly as mentioned above placed between the translucent plate and the support plate.

Advantageously, the module includes at least two cells each placed with its rear face bearing against a spacer-plate and a ribbon of conductive material extends in register with two adjacent spacer-plates with its elements in contact firstly with negative terminals belonging to a first photovoltaic cell bearing against a first spacer-plate, and secondly with positive terminals belonging to a second photovoltaic cell bearing against a second spacer-plate.

When the spacer-plate is provided with at least one cell-positioning rib, as mentioned above, provision may be made for said rib to be of a height that is greater than the thickness of the photovoltaic cell.

Advantageously, the tongues of the ribbon exert a resilient thrust force against the cell with the terminals of which they are in contact, which force urges the cells against the translucent plate.

The spacer-plate is rectangular in shape, a rib extends along each of its edges, the ribs of two opposite sides of the plate are spaced apart by a distance slightly greater than the length of the photovoltaic cell, and the ribs of two other opposite sides of the plate are spaced apart by a distance slightly greater than the width of the photovoltaic cell.

Finally, the invention provides a method of fabricating a module as mentioned above, which method comprises the steps consisting in:

a) assembling a plurality of spacer-plates together;

b) installing a plurality of ribbons on one side of the spacer-plates, the ribbons having their respective contact elements engaged in orifices in the spacer-plates;

c) placing a photovoltaic cell on another side of each spacer-plate, the rear face of said cell facing towards the spacer-plate and connection terminals of the cell being in register with orifices of the spacer-plate; and

d) installing the assembly as formed in this way between the translucent plate and the support plate.

Advantageously, during step d), the contact elements of the ribbons are taken from a waiting configuration to a configuration in which each of them exerts a resilient force against a connection terminal of the cell.

The invention can be better understood and other advantages thereof appear more clearly in the light of the following description of an embodiment of an electrical connection and support assembly, of a photovoltaic module, and of a method of fabricating such a module, given purely by way of example and made with reference to the accompanying drawings, in which:

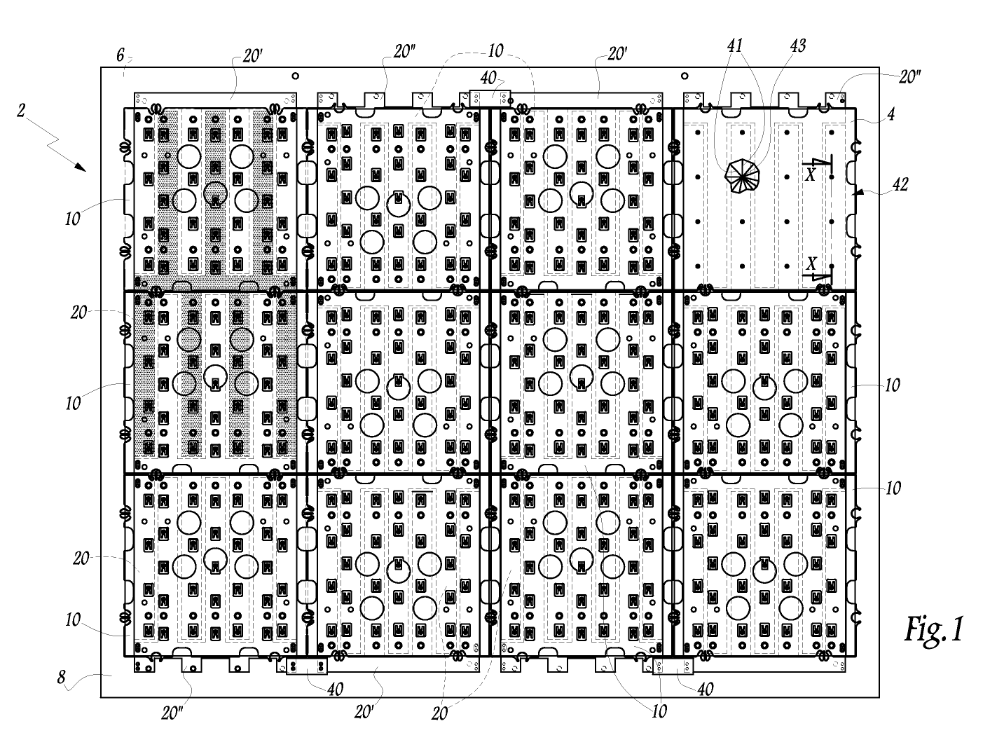

FIG. 1 is a front view of a photovoltaic module in accordance with the invention having only one of its photovoltaic cells shown, for clarity in the drawing;

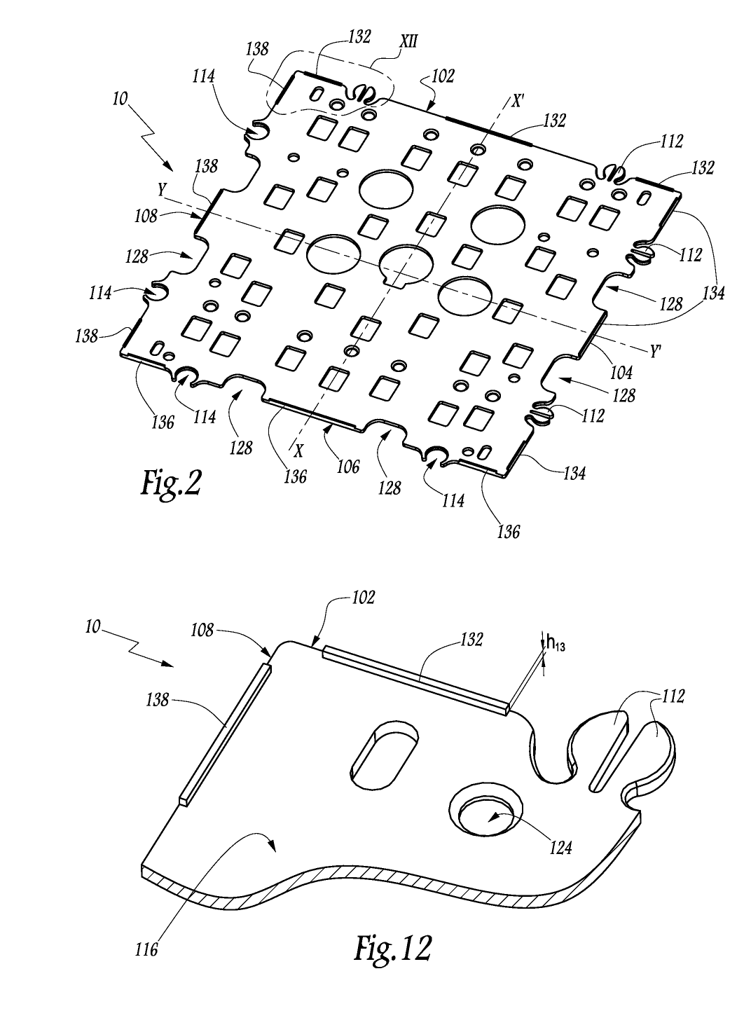

FIG. 2 is a perspective view of a spacer plate forming part of an electrical connection and support assembly of the FIG. 1 module;

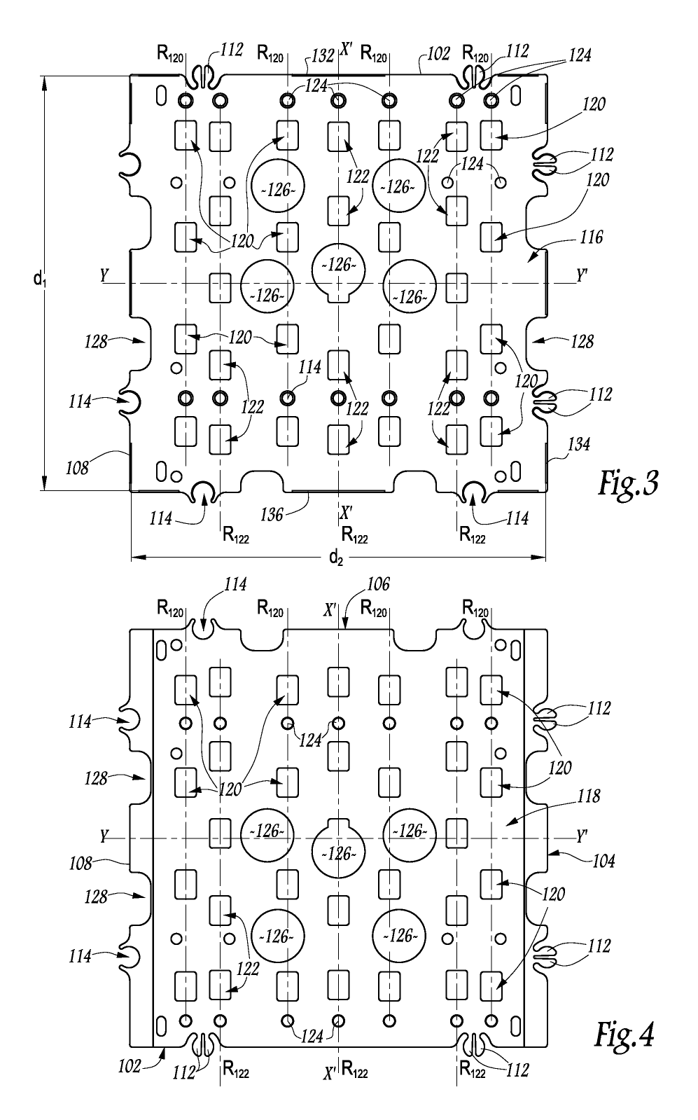

FIG. 3 is a front view of the FIG. 2 plate, seen from a first side;

FIG. 4 is a rear view of the plate of FIGS. 2 and 3, seen from a second side, opposite to the first side;

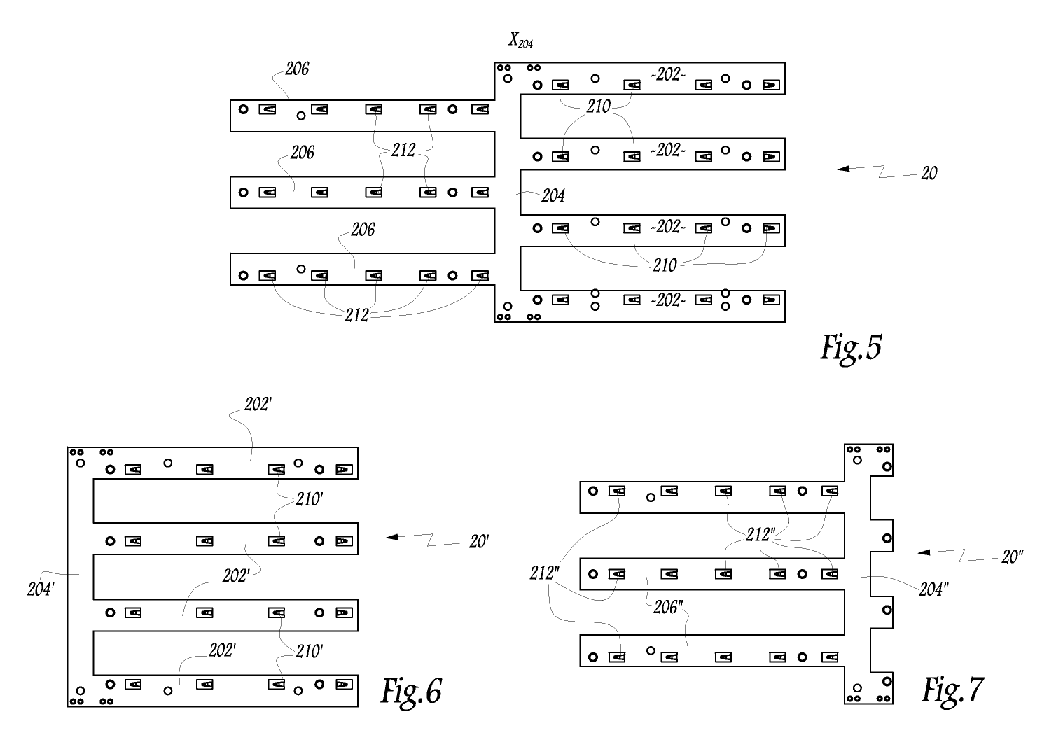

FIG. 5 is a front view of an interconnection ribbon suitable for use together with the plate of FIGS. 2 to 4;

FIGS. 6 and 7 are front views of other interconnection ribbons suitable for use with the plate of FIGS. 2 to 4;

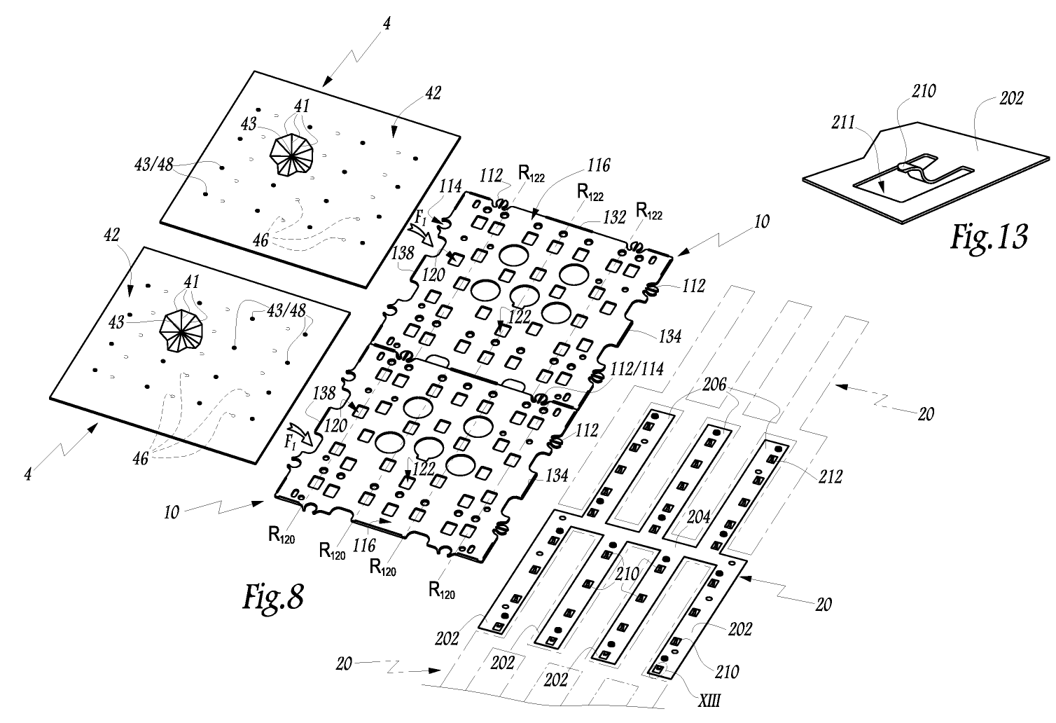

FIG. 8 is an exploded perspective view of two support plates, of an interconnection ribbon, and of two photovoltaic cells forming part of the FIG. 1 module;

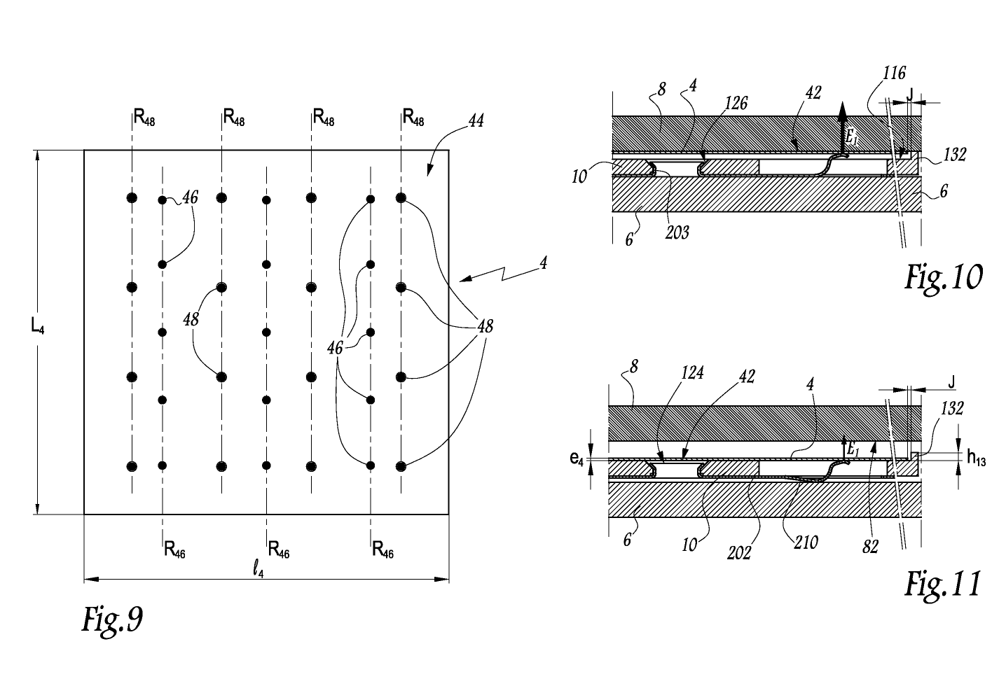

FIG. 9 is a view of one of the photovoltaic cells visible in FIGS. 1 and 8, seen from its side opposite from the side shown in those figures;

FIG. 10 is a diagrammatic section on a larger scale on line X-X in FIG. 1;

FIG. 11 is a section analogous to FIG. 10, during an intermediate step in the fabrication of the module;

FIG. 12 is a view on a larger scale showing a detail XII of FIG. 2; and

FIG. 13 is a view of a larger scale and from a different angle of the detail XIII in FIG. 8.

The photovoltaic module 2 shown in FIG. 1 comprises twelve photovoltaic cells, only one of which is shown in FIG. 1, where it is given reference 4. The photovoltaic cells are arranged between a support plate 6 that may be made of glass or some other opaque or translucent material that withstands bad weather and that is electrically insulating, and a front plate 8 that is translucent or transparent and that may be made of glass or of some other insulating material that withstands bad weather.

Each photovoltaic cell 4 has its front face 42 facing towards the front plate 8, and in use it is to be oriented towards the light of the sun. Electric current drains 41 meet at nodes 43 that are distributed over the front face 42, as can be seen in part in FIGS. 1 and 8. On its rear face 44, opposite from its front face 42 and visible in FIG. 9, each cell 4 is fitted with connection terminals of two types, namely positive connection terminals 46 and negative connection terminals 48. The positive connection terminals 46 are arranged in rows R₄₆ in positions that are determined by the distribution of the nodes 43 on the front face 42 of each cell 4. The negative terminals 48 are also arranged in rows, at a spacing that is a function of the distribution of the photosensitive components 41 on the front face 42. Thus, the cell 4 is a rear-contact cell and its front face 42 does not have any connection terminals. In the example shown, four rows R₄₈ of four negative terminals 48 are provided on the rear face 44, and three rows R₄₆ of five positive terminals are provided on the same rear face, each between two of the rows R₄₈.

Each cell 4 of the module 2 is placed on a spacer-plate 10 made of an electrically insulating material. In the meaning of the present invention, a material is electrically insulating if it presents electrical resistivity greater than 10⁸ ohm centimeters (Ω.cm).

In this example, each spacer plate 10 is made of a synthetic material that presents good ultraviolet performance and good temperature performance over a range extending from −40° C. to +110° C., that is non-flammable, and that can be recycled without giving off gas. It may comprise phenylene polysulfide (PPS) or some other material presenting comparable properties.

Each spacer-plate 10 is generally plane and of rectangular shape, having edges 102, 104, 106, and 108 that present portions in relief 112 and 114 for putting two adjacent plates into continuity. More precisely, the portions in relief 112 provided on the adjacent edges 102 and 104 of a plate 10 constitute projecting tips that may be received in hollow portions in relief formed by housings 114 of shape complementary to the shape of the tips 112 and formed in the edges 106 and 108 of an adjacent plate. It is thus possible to connect together two adjacent plates, by inserting the tips 112 of one of the plates in the housings 114 of the adjacent plate, as shown in FIGS. 1 and 8.

In practice, it is possible to provide two types of plate 10, referred to as “left” or “right” plates, depending on the distribution of the portions in relief 112 and 114 along their edges.

Reference 116 designates a first side or “first face” of the plate 10, as can be seen in FIGS. 2 and 3. Reference 118 designates a second side or “second face” of the plate 10, as can be seen in FIG. 4.

The plate 10 is provided with seven rows of orifices that are of rectangular section, namely four rows R₁₂₀ of four orifices 120, passing through the plate 10 between its sides 116 and 118, and three rows R₁₂₂ of five orifices 122, likewise passing through the plate 10 between its sides 116 and 118.

The plate 10 is also provided with fourteen orifices 124, that are of circular section and that are chamfered beside the face 116, these orifices being distributed over the surface of the plate and presenting a diameter that is relatively small, together with five orifices 126 that are likewise of circular or near-circular section, and that are of diameter that is greater than the diameter of the orifices 124.

Notches 128 are provided in the edges 104, 106, and 108 in each of the spacer plates 10.

The orifices 120, 122, 124, and 126, and the notches 128 make the spacer plates 10 lighter and make them less expensive to fabricate.

As can be seen more clearly from FIGS. 2 and 12, the edge 102 of each plate 10 is provided with a rib 132 that extends perpendicularly to its side 116 and that is interrupted in such a manner that it extends as three segments along the side 102. In the same manner, the edges 104, 106, and 108 are fitted with respective ribs 134, 136, and 138 that extend perpendicularly to the side 116 and that are likewise divided into three segments, being interrupted at the notches 128.

Two mutually perpendicular axes that are parallel to the side 116 of the plate 10 are referenced X-X′ and Y-Y′. The ribs 132 to 138 make it possible to pre-position at the photovoltaic cell placed on the side 116 of the plate 10, in translation along the axes X-X′ and/or Y-Y′. To do this, the ribs 132 and 136 are spaced apart in a direction parallel to the axis X-X′ by a distance d₁ that is slightly greater than the length L₄ of a cell 4 measured parallel to the rows R₄₆ and R₄₈. Likewise, the distance d₂ measured parallel to the axis Y-Y′ between the ribs 134 and 138 is slightly greater than the width l₄ of the same cell measured perpendicularly to the rows R₄₆ and R₄₈ and parallel to the faces 42 and 44. Thus, the ribs 132 to 138 form a kind of frame within which a cell 4 can be pre-positioned on the side 116 of a spacer plate 10, with small-amplitude movement being possible parallel to the axes X-X′ and Y-Y′.

The term “slightly greater” is used to mean that the distances d₁ and d₂ are greater than the dimensions L₄ and l₄ by less than 10%, and preferably by less than 5%.

If the cell is square, as is usual, then the dimensions L₄ and l₄ are equal, as are the distances d₁ and d₂.

Furthermore, a ribbon 20 extends under the two plates 10 that are visible in the top left portion of FIG. 1. This ribbon 20 is shown grayed solely for the purpose of making it easier to identify in the figure.

The ribbon 20 is made of a material that is electrically conductive, i.e. a material presenting a resistivity of less than 10⁻⁶ Ω.cm. For example, the ribbon 20 may be made of brass, of copper, of steel, or of a composite material of the copper and stainless steel type.

As can be seen more clearly in FIG. 5, the ribbon 20 has four strips 202 that are straight and mutually parallel and that extend from a central strip 204 from which the strips 202 are perpendicular. The ribbon 20 also has three strips 206 that are parallel to the strips 202, and thus perpendicular to the strip 204. The ribbon 20 is a single piece, the strips 202, 204, and 206 being made by being cut out from a sheet of metal.

A longitudinal axis of the strip 204 is referenced X₂₀₄. Relative to the strips 202, the strips 206 are situated on the opposite side of the strip 204. The strips 206 are offset along the axis X₂₀₄ relative to the strips 202. It is thus possible to align two ribbons 20 in a direction perpendicular to the axes X₂₀₄ of their respective strips 204 by engaging the strips 206 of one of the ribbons between the strips 202 of the other ribbon, as shown in FIG. 1.

Each of the strips 202 is fitted with four tongues 210 obtained by localized cutting out of the strip 202 and by folding it in such a manner that each tongue 210 extends in part perpendicularly to the plane of the strip 202 to which it belongs. In practice, a window 211 is cut out from the strip 202 about each tongue 210, which is then folded so as to project beyond the strip 202, perpendicularly to its side faces.

In the same manner, each strip 206 is fitted with five tongues 212 having the same shape as the tongues 210 and obtained in the same manner.

FIGS. 11 and 13 show the shape of a tongue 210 in a non-stressed configuration.

As can be seen in FIG. 8, a ribbon 20 may be placed simultaneously under two adjacent spacer-plates 10 so that its strips 202 extend under the rows R₁₂₀ of orifices 120 of a first spacer plate 10, while its strips 206 extend under the rows R₁₂₂ of the second spacer plate 10. The positioning of the tongues 210 on each of the strips 202 and 206 is such that the tongues then engage in the orifices 120 and 122.

Each spacer-plate 10 rests on the adjacent ribbon 20 via its side 118.

In FIG. 8, the positive terminals 46 of the cells 4 are represented by dashed lines since they are situated on the faces 44 of the cells that are not visible in this figure. As for the negative cells 48, they can be identified in this figure because they are in alignment through each cell 4 with the nodes 43.

Under such conditions, if a photovoltaic cell is placed on each of the plates 10 shown in FIG. 8, with its rows R₄₈ and R₄₆ of electrical terminals respectively in alignment with the rows R₁₂₀ and R₁₂₂ of said plate 10, it is possible to connect the terminals 48 of the cell 4 electrically to the strips 202 of a ribbon 20, by means of the tongues 210, and to connect the terminals 46 of another cell 4 placed on an adjacent spacer-plate 10, electrically to the strips 206 of the same ribbon 20, by means of the tongues 212. This connection takes place through the plate 10 that acts as a spacer by keeping each cell 4 spaced apart from the ribbons 20 and their equivalents situated on the other side of the plate 10.

Associating two plates 10 with a ribbon 20 thus makes it possible to connect the negative terminals 48 of a first cell 4 to the positive terminals 46 of another cell 4.

Connection takes place between the cells 4 and the ribbons 20 by resilient pressure between the tongues of 210 and 212 against the terminals 48 and 46 respectively, without soldering, without adhesive, and without using a printed circuit, with this being easy to implement, robust, reliable, and inexpensive. In other words, the electrical contact between the terminals 46 and 48 and the tongues 210 and 212 may be said to be “free” since it is established without any permanent fastener means, in particular without soldering and without adhesive, solely under the effect of the resilient force exerted by the tongues.

It can be understood that the situation shown for two cells 4 in FIG. 8 may be repeated by placing the conductive strips 206 of another ribbon 20 between the conductive strips 202 of the ribbon shown in FIG. 8, as shown in chain-dotted lines, such that the tongues 212 of the strips 206 of this second ribbon come into register with the orifices 122 of the spacer plate 10 shown towards the bottom of FIG. 8, and make contact with the terminals 46 of the photovoltaic cell 4 placed on said plate. Likewise, and as shown in chain-dotted lines, the strips 202 of another ribbon 20 may be placed between the strips 206 of the ribbon 20. This operation may be repeated as many times as there are photovoltaic cells within a column for connecting in intermediate positions.

The strips 202 and 206 of a ribbon 20 are used for collecting electricity from the terminals 46 or 48 of a photovoltaic cell 4, whereas the central strip 204 serves to distribute this electricity between the various strips 202 and 206 to which it is perpendicular.

Thus, two ribbons 20 are located in part under each spacer-plate 10, such that one cell 4 placed on the side 116 of a spacer plate 10 is in contact with each of these two ribbons via its terminals 46 and 48 respectively.

Each cell 4 is thus associated with a connection and support assembly that comprises a spacer-plate 10 and two ribbons 20 or their equivalent, and that is located between the plates 6 and 8 of the model.

As can be seen in FIGS. 6 and 7, certain particular ribbons 20′ and 20″ may be used at the ends of a column, a ribbon 20′ being placed for example in the top left portion of FIG. 1, whereas a ribbon 20″ is placed in the bottom left portion of the same figure. Each of the ribbons 20′ has a distributor strip 204′ and four current-collector strips 202′, each fitted with four tongues 210′ having the same configuration as the tongues 210. Each of the ribbons 20″ comprises a distributor strip 204″ and three current-collector strips 206″ having the same configuration as the strips 206 and each carrying five tongues 212″ having the same configuration as the tongues 212.

A connection assembly associated with a cell 4 may thus equally well comprise a spacer-plate 10, a ribbon 20, and a ribbon 20′, or a spacer-plate 10, a ribbon 20, and a ribbon 20″. For a module 2 having only one cell 4, the connection assembly of the module comprises a spacer-plate 10, a ribbon 20′, and a ribbon 20″.

As can be seen in FIG. 1, connectors 40 are used to put the ribbons 20, 20′, and 20″ of each column into electrical continuity. More precisely, a connector connects a ribbon 20′ of one column to a ribbon 20″ of an adjacent column, at one end of these columns.

The height of a rib 132 to 138 relative to the side 116 of a spacer-plate 10 is written h₁₃. This height is strictly greater than the thickness e₄ of a photovoltaic cell 4, as measured between its faces 42 and 44, perpendicularly to the dimensions L₄ and l₄.

When a module such as the module 2 shown in FIG. 1 is to be fabricated, the first thing to be done is to determine the number of photovoltaic cells of the module, which number is twelve in the example shown. A corresponding number of spacer-plates 10 is then assembled in the configuration desired for the module by using their complementary portions in relief 112 and 114.

The ribbons 20, 20′, and 20″ are then put into place as a function of the connection mode desired for the various cells 4 on the sides 118 of the various spacer-plates 10

In this configuration, the tongues 210, 212, 210′, and 212″ of the ribbons are waiting to make contact with the terminals of the cells.

The various ribbons 20, 20′, and 20″ are then secured to the various spacer-plates 10 by plastically deforming a portion 203 of each tongue 202 or 206, and by inserting it in an orifice 124. This use of plastic deformation for fastening purposes serves, in the example of FIG. 1, to constitute an assembly of twelve spacer-plates 10, eight ribbons 20, four ribbons 20′, and four ribbons 20″ capable of receiving twelve photovoltaic cells 4.

The assembly made up of the plates 10 assembled to the ribbons 20, 20′, and 20″ is then placed on the plate 6 on which it rests via curved portions 210A of the tongues 210 and curved portions of the other tongues.

The cells 4 are then put into place on the spacer-plates while aligning the rows R₄₆ and R₄₈ respectively on the rows R₁₂₂ and R₁₂₀, as represented by arrows F₁ in FIG. 8.

When the cells 4 are in place on the spacer-plates 10, the rows R₄₆ of terminals 46 of one cell 4 are connected to the rows R₄₈ of terminals 48 of an adjacent cell or to the end of a column of cells 4 by means of a ribbon 20, 20′, or 20″.

Each cell 4 then bears against the side 116 of a spacer-plate 10, having is movements parallel to the axes X-X′ and Y-Y′ of said plate 10 limited by the ribs 132 to 138, and by bearing against the tongues 210 and 212 of two distinct ribbons 20, 20′, or 20″. More precisely, each photovoltaic cell 4 is in contact via its terminals 46 or 48 with the tongues 210 or 210′ of a ribbon 20 or 20′ and the tongues 212 or 212″ of another ribbon 20 or 20″.

This produces the configuration in FIG. 11 in which it can be seen that a tongue 210 is formed in such a manner that it projects relative to the main surface of the strip 202 in which it is formed, away from the spacer-plate 10, i.e. downwards in the figure.

In this configuration, the resilient force E₁ exerted by the tongues 210, 212, 210′, or 212″ of the ribbons against the terminals 46 for 48 of the cells is of relatively low magnitude. In a variant, a provision may even be made for the shape of the tongues in this configuration to be such that the resilient force is of practically zero magnitude, or even that the tongues that do not make any contact with the terminals.

When the module 2 is assembled, the support plate 6 is placed under the plates 10 and the ribbons 20, 20′, and 20″, i.e. opposite from the cells 4. The transparent plate 8 is then placed above the cells 4 that rest against the plates 10, i.e. against their front faces 42.

By moving the plates 6 and 8 towards each other, i.e. by going from the configuration of FIG. 11 to the configuration of FIG. 10, the ribs 132 to 138 are caused to bear against the face 82 of the plate 8 that faces towards the cells 4. Since the thickness e₄ is less than the height h₁₃, the ribs 132 to 138 protect the cells 4 mechanically from impact against the plate 8.

This approach also has the effect of pushing the portions 210A and their equivalents of the tongues 210 and their equivalents into the orifices 120 and 122, thereby increasing the magnitude or the strength of the resilient force E₁, or creating this force if it does not already exist from the previous step.

Each of the various tongues 210 thus exerts a resilient force E₁ on the plate 4 with which it is in electrical contact via a terminal 48, which force pushes the photovoltaic cell 4 against the front plate 8, thereby ensuring that the cell 4 is well positioned to recover a maximum quantity of light rays through the plate 8. A comparable resilient force is exerted by the tongues 212 via the terminals 46 of the cell 4. In practice, as a function of the thickness of the ribbons 20, 20′, and 20″ the tongues 210, 212 and their equivalents may be dimensioned and folded in such a manner that the resilient force E₁ exerted by each of them in the close-together configuration of the plates 6 and 8 presents a magnitude greater than 0.5 newtons (N).

In other words, the structure of spacer-plates 10 and of the ribbons 20, 20′, and 20″ enables the various photovoltaic cells 4 to be pressed against the front face 8 while making electrical contact between the various tongues 210 and 212 and the terminals 46 and 48 of the cells 4 reliable, and while guaranteeing that this contact is made by virtue of the resilient force E₁. The spacer-plates then maintain the spacing between the plates 6 and 8.

As can be seen more particularly from FIGS. 10 and 11, the cells 4 are molded with clearance J relative to the ribs 132 to 138, by virtue of the difference between the distances d₁ and d₂ and the dimensions L₄ and l₄, thereby avoiding mechanical stresses during movement of the cells 4 under the effect of the tongues 210 and 212 while the plates 6 and 8 are moving towards each other.

The transverse dimensions of the orifices 120 and 122 are compatible with the fact that the tongues 210 and 212 remain bearing respectively against the terminals 48 and 46, even if a cell slides over the front face 116 of the plate against which it is resting, within the limits defined by the ribs 132 to 138. In practice, the clearance J is small enough to guarantee that the tongues 210, 212, 210′, and 212″ are properly positioned relative to the connection terminals 46 and 48.

In addition, the spacer-plates 10 guarantee height that is constant between the plats 6 and 8, insofar as the ribs 132 to 138 form distributed bearing zones between the spacer-plates 10 and the front plate 8, while the spacer-plates 10 rest on the support plate 6 via the ribbons 20, 20′, and 20″.

The above-mentioned cells 4 as shown in the figures comprise one particular example with a particular lay-out of the contact terminals 46 and 48. The invention can be implemented with any type of photovoltaic cell having rear contact terminals, the configuration of the spacer-plates 10 and of the ribbons 20, 20′, and 20″ being adapted to the lay-out of these contact terminals 46 and 48.

1. An assembly for electrically connecting a photovoltaic cell having rear contacts, a front face for facing towards the light, and a rear face fitted with positive electrical connection terminals and with negative electrical connection terminals, the assembly being characterized in that it comprises:
at least one spacer-plate of electrically insulating material suitable for having the rear face of the cell bear against a first side thereof in a position such that the connection terminals are in register with orifices passing through the spacer-plate; and
at least two ribbons of electrically conductive material arranged on a second side of the spacer-plate, opposite from the first side, and each provided with contact elements suitable for establishing electrical contact with the connection terminals of the cell bearing against the first side of the spacer-plate, through the orifices in the spacer-plate, electrical contact between the contact elements and the connection terminals being established without soldering, under the effect of a resilient force.

2. An assembly according to claim 1, wherein the spacer-plate is provided with at least one rib for prepositioning the cell in two directions that are parallel to a face of the cell.

3. An assembly according to claim 2, wherein the spacer-plate is provided with a plurality of ribs that are compatible with mounting a photovoltaic cell with clearance.

4. An assembly according to claim 1, wherein each ribbon comprises a plurality of electricity-collector strips, each fitted with a plurality of contact elements, and an electricity distributor strip connecting together the collector strips.

5. An assembly according to claim 4, wherein the collector strips of the ribbon extend on either side of the distributor strip and are perpendicular thereto, and wherein the collector strips situated on one side of the distributor strip are offset along a longitudinal axis of the distributor strip relative to the collector strips situated on the other side of the distributor strip.

6. An assembly according to claim 1, wherein the spacer-plate is provided with at least a first row of orifices for placing in resister with negative terminals of a photovoltaic cell pressing against said spacer-plate, and a second row of orifices for placing in register with positive terminals of the same cell bearing against said spacer-plate.

7. An assembly according to claim 1, wherein the contact elements of the ribbons are elastically deformable tongues.

8. An assembly according to claim 7, wherein the tongues are obtained by cutting out and/or folding the ribbons.

9. An assembly according to claim 1, wherein the contact elements are formed integrally with the ribbons.

10. A photovoltaic module comprising at least one photovoltaic cell having rear contacts, a translucent plate covering the front face of the photovoltaic cell, and a support plate towards which the rear face of the cell faces, the module being characterized in that it includes at least one support and connection assembly according to any preceding claim placed between the translucent plate and the support plate.

11. A module according to claim 10, wherein it includes at least two cells each placed with its rear face bearing against a spacer-plate and at least one ribbon of conductive material extends in register with two adjacent spacer-plates with its elements in contact firstly with negative terminals of a photovoltaic cell bearing against a first spacer-plate, and secondly with positive terminals of a photovoltaic cell bearing against a second spacer-plate.

12. A module according to claim 10, wherein the support and positioning assembly is according to claim 2, and wherein the positioning rib provided on the spacer-plate is of a height greater than the thickness of the photovoltaic cell.

13. A module according to claim 10, wherein the tongues of the ribbon exert a resilient thrust force against the cell with the terminals with which they are in contact, which force urges the cells against the translucent plate.

14. A module according to claim 10, wherein the spacer-plate is rectangular in shape, in that a rib extends along each of its edges, in that the ribs of two opposite sides of the plate are spaced apart by a distance slightly greater than the length of the photovoltaic cell, and wherein the ribs of two other opposite sides of the plate are spaced apart by a distance slightly greater than the width of the photovoltaic cell.

15. A method of fabricating a photovoltaic module according to claim 10, the method being characterized in that it comprises the steps consisting in:
a) assembling a plurality of spacer-plates together;
b) installing a plurality of ribbons on one side of the spacer-plates, the ribbons having their respective contact elements engaged in orifices in the spacer-plates;
c) placing a photovoltaic cell on another side of each spacer-plate, the rear face of said cell facing towards the spacer-plate and connection terminals of the cell being in register with orifices of the spacer-plate; and
d) installing the assembly as formed in this way between the translucent plate and the support plate.

16. A method according to claim 15, wherein during step d), the contact elements of the ribbons are taken from a waiting configuration to a configuration in which each of them exerts a resilient force against a connection terminal of the cell.
